(19) United States
(12) Patent Application Publication
(10) Pub. No.: US 2012/0181899 A1
(43) Pub. Date: Jul. 19, 2012

(54) Piezoelectric resonator and elastic wave device

(75) Inventor: Mitsuaki Koyama, Sayama-shi (JP)

(73) Assignee: NIHON DEMPA KOGYO CO., LTD., Shibuya-ku (JP)

(21) Appl. No.: 13/374,773

(22) Filed: Jan. 11, 2012

(30) Foreign Application Priority Data
Jan. 18, 2011 (JP) 2011-008197

(51) Int. Cl. H01L 41/04

(52) U.S. Cl. 310/313 R; 310/326

(57) ABSTRACT

The generation of secondary vibration different in oscillation frequency from primary vibration is suppressed. In a quartz-crystal resonator in which excitation electrodes are formed respectively on both surfaces of a quartz-crystal piece whose primary vibration is thickness shear vibration, a hole portion is formed at a portion, in the excitation electrode, where secondary vibration is generated, and a concave portion is formed in a region, in the quartz-crystal piece, corresponding to the hole portion. Alternatively, a convex portion are preferably provided symmetrically with respect to a center of the quartz-crystal resonator. Consequently, the secondary vibration attenuates and the oscillation frequency of the secondary vibration shifts to a high frequency side.

### BACKGROUND OF THE INVENTION

1. Field of the Invention

The present invention relates to a piezoelectric resonator and an elastic wave device in which the generation of secondary vibration is suppressed.

2. Description of the Related Art

Piezoelectric resonators are used in various fields such as electronic devices, measuring instruments, and communication devices, and especially an AT-cut quartz-crystal resonator whose primary vibration is thickness shear vibration is often used because of its good frequency characteristic, but it has a problem that unnecessary secondary vibration is generated. Unnecessary secondary vibration, if generated, is coupled to primary vibration, which involves a concern about the occurrence of a frequency jump. The generation of some secondary vibration is ascribable to inharmonic overtone (hereinafter, “overtone”). This overtone vibration is thickness vertical vibration and the level of its amplitude is sometimes equivalent to the level of an amplitude of thickness shear vibration which is the primary vibration, and it is preferable to prevent its generation or shift its oscillation frequency away from an oscillation frequency of the primary vibration. Further, when the primary vibration is, for example, thickness shear vibration, other kinds of secondary vibration such as contour shear vibration can be secondary vibration. These secondary vibrations will be a cause of the generation of activity dips and frequency dips.

Here, as a method of suppressing the secondary vibration of the thickness shear vibration, there has been known a method of confining energy by making an electrode area small. However, when the oscillation frequency is over 20 MHz, an effect of confining energy decreases, and therefore this method has difficulty in suppressing the secondary vibration under the current situation where quartz-crystal resonators whose oscillation frequencies are over 50 MHz are generally used.

Further, chamfering an end portion of a quartz-crystal piece or changing the shape of a quartz-crystal piece into a projecting shape or the like is also in practice in order to suppress the secondary vibration, but since there is an increasing demand for quartz-crystal resonators that are compact and high in oscillation frequency in accordance with the downsizing of electronic devices, there is a limit to the suppression of the secondary vibration by such a change of the shape. Another known method is to mechanically suppress the generation of the secondary vibration by giving a load of an adhesive or the like to a position, in a quartz-crystal piece, where the secondary vibration is generated, but due to the generation of gas from the adhesive or the application of a stress to the quartz-crystal piece, it might not be possible to ensure long-term stability of the frequency.

Further, Patent Document 1 describes a structure in which a recess is provided in a primary surface of a piezoelectric plate, and Patent Document 2 describes a structure in which holes are provided in electrode tab portions and a pocket is provided in a quartz-crystal blank. Further, Patent Document 3 describes a structure in which an opening portion is formed in an excitation electrode, and Patent Document 4 describes a structure in which a recessed part is formed in a quartz-crystal piece in order to suppress the secondary vibration. However, even by using these techniques, it is not possible to shift the oscillation frequency of the overtone vibration to a range not affecting the primary vibration, and the problem of the present invention cannot be solved.

[Patent Document 1] Japanese Patent Application Laid-open No. Sho 60-58709 (FIG. 4)

[Patent Document 2] Japanese Patent Application Laid-open No. Hei 01-265712 (FIG. 1, FIG. 3)

[Patent Document 3] Japanese Patent Application Laid-open No. 2001-257560 (paragraph 0007, FIG. 1)

[Patent Document 4] Japanese Patent Application Laid-open No. Hei 06-338755 (paragraphs 0012, 0014)

### SUMMARY OF THE INVENTION

The present invention was made under such circumstances and has an object to provide a technique that is capable of suppressing the generation of secondary vibration or shifting a frequency of the secondary vibration in a piezoelectric resonator or an elastic wave device.

As a solution, a piezoelectric resonator of the present invention includes:

a piezoelectric body in a plate shape;

excitation electrodes provided on both surfaces of the piezoelectric body; and

a secondary vibration suppressing part including a hole portion formed in the excitation electrode and a concave portion or a through hole formed in a region, in the piezoelectric body, corresponding to the hole, to suppress secondary vibration different in oscillation frequency from primary vibration of the piezoelectric body.

Another invention is a piezoelectric resonator including:

a piezoelectric body in a plate shape;

excitation electrodes provided on both surfaces of the piezoelectric body; and

a secondary vibration suppressing part including a convex portion provided on a portion, in the piezoelectric body, apart from the excitation electrode, to suppress secondary vibration different in oscillation frequency from primary vibration of the piezoelectric body.

Still another invention is an elastic wave device in which an IDT electrode is provided on a surface of a piezoelectric body in a plate shape, the device including

a secondary vibration suppressing part including a hole portion formed in the IDT electrode and a concave portion or a through hole formed in a region, in the piezoelectric body, corresponding to the hole portion, to suppress an elastic wave with a frequency different from a target frequency band taken out from an output port.

Yet another invention is an elastic wave device in which an IDT electrode is provided on a surface of a piezoelectric body in a plate shape, the device including

a secondary vibration suppressing part including a convex portion provided on a portion, in the piezoelectric body, apart from the IDT electrode, to suppress an elastic wave with a frequency different from a target frequency band taken out from an output port.

In the present invention, in the region, in the piezoelectric resonator, where the secondary vibration is generated, the hole portion (the concave portion or the through hole) is formed from the excitation electrode to the piezoelectric body. Further, in another invention, in the region, in the piezoelectric resonator, where the secondary vibration is generated, the convex portion is formed on the portion, in the piezoelectric body, apart from the excitation electrode. Therefore, the generation of the secondary vibration is suppressed. Concretely, it is possible to reduce energy of the secondary vibration or shift the frequency of the secondary vibration away from the frequency of the primary vibration. This makes it possible to suppress the occurrence of a frequency jump in the piezoelectric resonator.

In still another invention, since at a predetermined position of the elastic wave device, the concave portion or the through hole is formed from the IDT electrode to the piezoelectric body, it is possible to suppress the elastic wave with the frequency different from the target frequency band, resulting in a good characteristic of the elastic wave device.

### BRIEF DESCRIPTION OF THE DRAWINGS

FIG. 1 is a plane view and a cross-sectional view showing an example of a quartz-crystal resonator according to a first embodiment of the present invention;

FIG. 2(a) to FIG. 2(d) are process views showing an example of a method of manufacturing the quartz-crystal resonator;

FIG. 3(a) to FIG. 3(c) are process views showing the example of the method of manufacturing the quartz-crystal resonator;

FIG. 4(a) to FIG. 4(d) are process views showing an example of another method of manufacturing the quartz-crystal resonator;

FIG. 5(a) and FIG. 5(d) are process views showing an example of still another method of manufacturing the quartz-crystal resonator;

FIG. 6 is a plane view showing another example of the quartz-crystal resonator according to the first embodiment;

FIG. 7(a) to FIG. 7(c) are cross-sectional views showing other examples of the quartz-crystal resonator according to the first embodiment;

FIG. 8(a) and FIG. 8(b) are explanatory views showing regions where secondary vibration is generated in the quartz-crystal resonator;

FIG. 9 is a plane view showing another example of the quartz-crystal resonator according to the first embodiment;

FIG. 10 is a cross-sectional view showing another example of the quartz-crystal resonator according to the first embodiment;

FIG. 11 is a plane view showing an example of a quartz-crystal resonator according to a second embodiment of the present invention;

FIG. 12 is a cross-sectional view of the quartz-crystal resonator taken along A-A line in FIG. 11;

FIG. 13 is a cross-sectional view showing another example of the quartz-crystal resonator according to the second embodiment;

FIG. 14(a) and FIG. 14(b) are explanatory charts showing states of the suppression of secondary vibration, which is an effect of the present invention;

FIG. 15 is a plane view showing still another example of the quartz-crystal resonator according to the embodiment of the present invention;

FIG. 16 is a vertical sectional view showing an example of an etching amount sensor including the quartz-crystal resonator according to the embodiment of the present invention; and

FIG. 17(a) and FIG. 17(b) are characteristic charts showing a correlation between an oscillation frequency and admittance of the quartz-crystal resonator of the present invention.

### DETAILED DESCRIPTION OF THE PREFERRED EMBODIMENTS

### First Embodiment

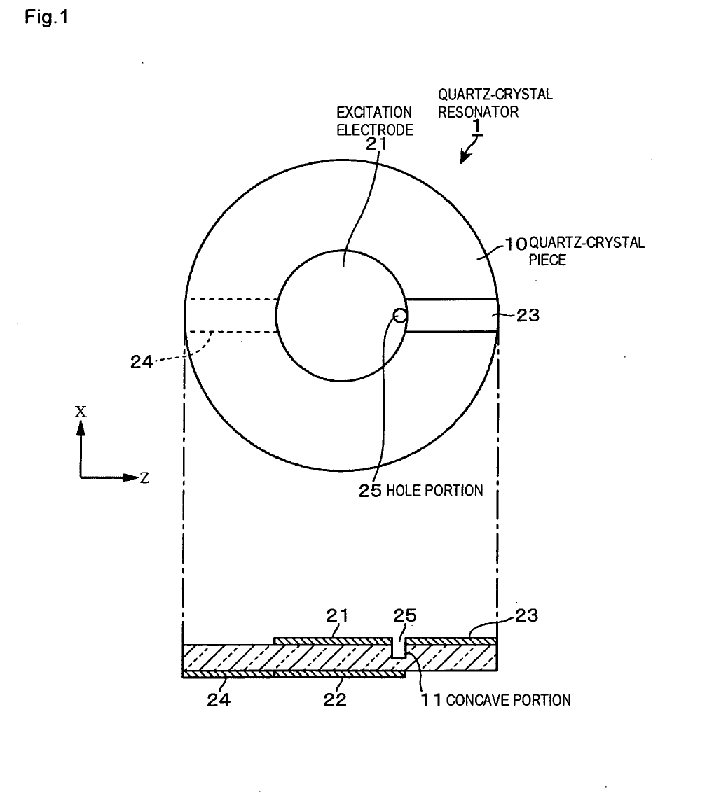

Hereinafter, an embodiment of a quartz-crystal resonator being a piezoelectric resonator of the present invention will be described. As shown in FIG. 1, this quartz-crystal resonator 1 includes excitation electrodes 21, 22 respectively on both surfaces of a quartz-crystal piece 10 being a piezoelectric body. As the quartz-crystal piece 10, an AT-cut quartz-crystal piece in a fundamental mode is used, for instance, and the quartz-crystal piece 10 is structured so that thickness shear vibration being its primary vibration has a 30 Hz oscillation frequency. In this example, the quartz-crystal piece 10 is formed in a circle shape in plane view, for instance, and its diameter is set to, for example, φ8.7 and its thickness is set to 0.186 mm.

The excitation electrodes 21, 22 are formed at center portions of the both surfaces of the quartz crystal piece 10 so as to face each other in order to excite the quartz-crystal piece 10. These excitation electrodes 21, 22 are formed in a circular shape, for instance, and their diameters are set to about φ5 mm. Further, a lead electrode 23 is connected to part of the excitation electrode 21 on the one surface so as to be led toward a peripheral edge of the quartz-crystal piece 10, and a lead electrode 24 is connected to part of the excitation electrode 22 on the other surface so as to be led toward the peripheral edge opposite the peripheral edge to which the lead electrode 23 is led. The direction in which these lead electrodes 23, 24 are led is a Z-axis direction of the quartz-crystal piece 10 as shown in FIG. 1. The excitation electrode 21 and the lead electrode 23 on the one surface are integrally formed, and the excitation electrode 22 and the lead electrode 24 on the other surface are integrally formed. These electrodes are each made of a laminate film of chromium (Cr) and gold (Au), for instance.

Furthermore, a hole portion 25 with a predetermined size is formed at a predetermined position of the excitation electrode 21 on the one surface, and in the one surface of the quartz-crystal piece 10, a concave portion 11 equal in size to the hole portion 25 is formed under the hole portion 25. That is, in the one surface of the quartz-crystal piece 10, the concave portion 11 continuing to the hole portion 25 is formed. These hole portion 25 and concave portion 11 correspond to a secondary vibration suppressing part.

These hole portion 25 and concave portion 11 are formed to suppress the generation of secondary vibration different in oscillation frequency from the primary vibration, in this example, overtone vibration generated in the Z-axis direction of the piezoelectric piece 10 and higher in oscillation frequency than the primary vibration. Therefore, these hole portion 25 and concave portion 11 are formed with predetermined sizes at a position, of the excitation electrode 21, where they suppress the generation of the overtone vibration. Here, suppressing the generation of the secondary vibration includes not only a case where the generation of the secondary vibration is completely prevented but also a case where a gain of the secondary vibration is attenuated.

Further, the shape of the excitation electrodes 21, 22 is appropriately set, and the excitation electrodes 21, 22 may be formed to extend up to the vicinity of the outer edge of the quartz-crystal piece 10. Further, a planar shape of the hole portion 25 and the concave portion 11 may be any shape such as a circular shape, a quadrangular shape, a triangular shape, or a rhombus shape, provided that it is a shape having a size with which they can prevent the generation of the secondary vibration, and a depth of the concave portion 11 is also appropriately set.

In practice, the shape of the excitation electrodes 21, 22 and the position and sizes of the hole portion 25 and the concave portion 11 are decided by using a simulator so that the generation of the secondary vibration being a suppression target can be suppressed. As for an example of the sizes of the hole portion 25 and the concave portion 11, when the hole portion 25 and the concave portion 11 are formed in a circular shape, their diameter is about 1.1 mm and the depth of the concave portion 11 is about 0.02 mm.

Further, the concave portion 11 is formed in a region, in the quartz-crystal piece 10, corresponding to the hole portion 25 of the excitation electrode 21, and the region corresponding to the hole portion 25 means a region under the hole portion 25, and a case where the concave portion 11 is formed to have a planar shape different from that of the hole portion 25 in a process where the concave portion 11 is formed is also included.

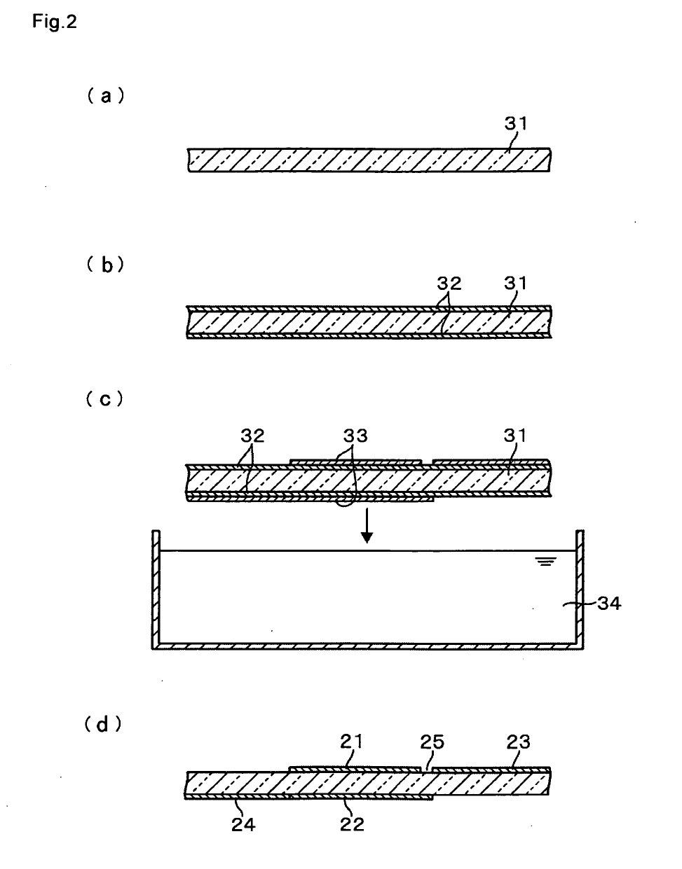

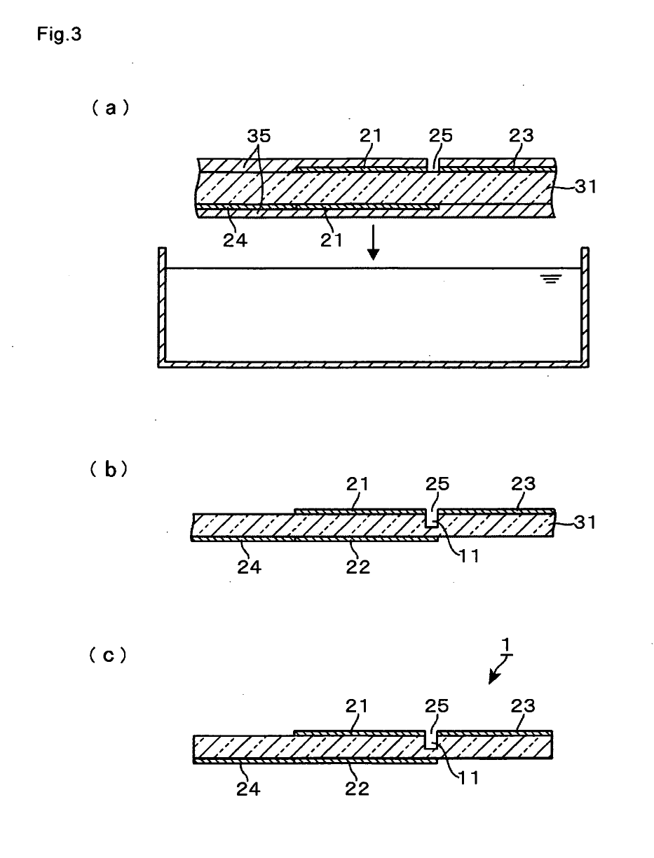

Next, a method of manufacturing the quartz-crystal resonator 1 will be described with reference to FIG. 2(a) to FIG. 2(d) and FIG. 3(a) to FIG. 3(c). Note that FIG. 2(a) to FIG. 2(d) and FIG. 3(a) to FIG. 3(c) illustrate one quartz-crystal resonator fabricated in part of one quartz-crystal substrate. First, after the cut quartz-crystal substrate 31 is polished and washed (FIG. 2(a)), electrode films (metal films) 32 in which, for example, Au is stacked on Cr are formed on both surfaces of the quartz-crystal substrate 31 by vapor deposition or sputtering as shown in FIG. 2(b).

Next, electrode patterns of the excitation electrodes 21, 22 and the lead electrodes 23, 24, and the hole portion 25 are formed by wet etching. For example, as shown in FIG. 2(c), a resist pattern 33 corresponding to the positions and shapes of the electrode patterns and the hole portion 25 is formed on the one surface of the quartz-crystal substrate 31. Subsequently, the quartz-crystal substrate 31 is immersed in a KI (potassium iodide) solution 34, whereby exposed portions of the electrode films 32 (metal films) are etched, so that metal film patterns in which the electrode patterns and the hole portion 25 are formed are obtained (refer to FIG. 2(d)). Incidentally, the electrode patterns and the hole portion 25 may be formed in separate processes.

Thereafter, as shown in FIG. 3(a) to FIG. 3(c), the concave portion 11 is formed at a predetermined position of the quartz-crystal substrate 31 by wet etching. Concretely, the both surfaces of the quartz-crystal substrate 31 is covered by covers 35 so that only the hole portion 25 is opened, and the quartz-crystal substrate 31 is immersed in, for example, a hydrofluoric acid solution and is etched, with the covers 35 being used as masks, whereby the concave portion 11 is formed as shown in FIG. 3(b). Here, the covers 35 are made of a material that is etched by the hydrofluoric acid solution at a lower rate than quartz crystal. Thereafter, the covers 35 are removed and the quartz-crystal resonator 1 is cut out from the quartz-crystal substrate 31 (refer to FIG. 3(c)).

According to the quartz-crystal resonator 1 of the present invention, since, in the excitation electrode 21 on the one surface, the hole portion 25 is formed at the position where it suppresses the generation of the secondary vibration, the excitation electrode on the one surface is not present in this region, which makes it difficult for the vibration to occur, and therefore, a gain of the secondary vibration in this region attenuates.

Further, since the concave portion 11 is formed at the position, in the quartz-crystal piece 10, corresponding to the hole portion 25, the oscillation frequency of the secondary vibration shifts toward a high frequency side. Specifically, a quartz-crystal resonator has a side-ratio effect that its oscillation frequency becomes higher as a ratio of an outside dimension of the quartz-crystal resonator to an area of an excitation electrode becomes smaller. The side ratio is a value found by the excitation electrode area/quartz-crystal piece thickness, and the oscillation frequency is higher when the side ratio is large than when it is small. Therefore, when the concave portion 11 is formed in the quartz-crystal piece 10, the oscillation frequency of the secondary vibration shifts toward the high frequency side because the outside dimension of the quartz-crystal piece 10 becomes small in this portion.

Therefore, according to the quartz-crystal resonator 1 of the present invention, since the hole portion 25 is formed in the excitation electrode 21 and the concave portion 11 is formed in the quartz-crystal piece 10, the gain of the secondary vibration attenuates and the oscillation frequency of the secondary vibration shifts toward the high frequency side. On the other hand, since the oscillation frequency of the primary vibration does not change, a frequency difference between the oscillation frequency of the primary vibration and the oscillation frequency of the secondary vibration becomes large, which can suppress the occurrence of an adverse effect by the secondary vibration, for example, suppress a frequency jump.

As described above, in the quartz-crystal resonator 1 of the present invention, it is important to form the hole portion 25 in the excitation electrode 21 and form the concave portion 11 in the quartz-crystal piece 10. If only the hole portion 25 in the excitation electrode 21 is formed and the concave portion 11 in the quartz-crystal piece 10 is not formed, the secondary vibration, though it can be attenuated to some degree, can be attenuated only to a small degree and it is not possible to change the oscillation frequency of the secondary vibration.

Further, in a structure in which the concave portion 11 is formed in the quartz-crystal piece 10 and the excitation electrode is formed on a surface of the concave portion 11, the secondary vibration is driven by the excitation electrode and therefore, a degree of the attenuation of the secondary vibration is small and a change amount of the oscillation frequency of the secondary vibration is small, which makes it difficult to ensure the effect of the present invention. Further, in a structure in which the hole portion 25 is formed not in the excitation electrode 11 but in a formation region of the lead electrode 23 (24) and the concave portion 11 is formed in a region, in the quartz-crystal piece 10, corresponding to the hole portion 25, the lead electrode functions as part of a driving electrode, though only to a slight degree, and therefore, the degree of the attenuation of the secondary vibration is small and the effect of changing the oscillation frequency of the secondary vibration cannot be obtained.

Furthermore, in the present invention, since the hole portion is formed in the excitation electrode and the concave portion is formed in the quartz-crystal piece, it is possible to combine this structure with the chamfering of an end portion of the quartz-crystal piece or changing of the shape of the quartz-crystal piece such as the formation of the quartz-crystal piece in a projecting shape, which makes it possible to suppress the generation of the secondary vibration more.

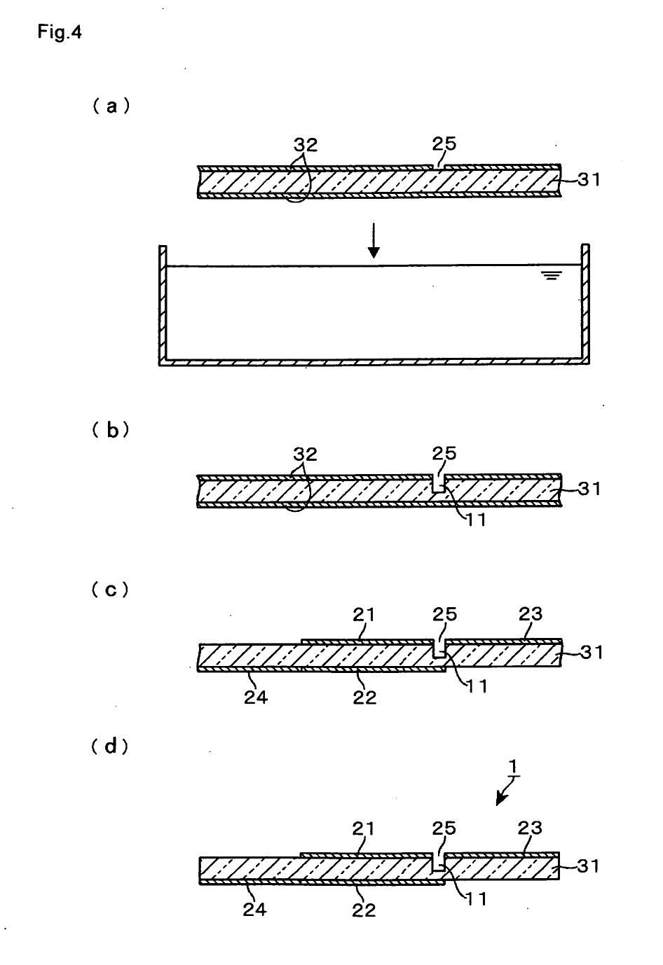

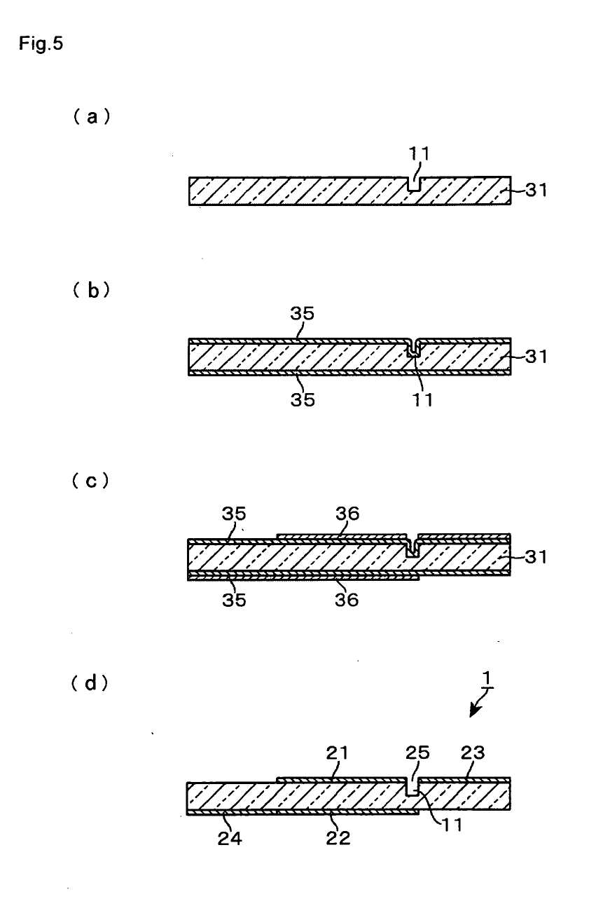

In the above, the quartz-crystal resonator 1 of the present invention may be manufactured by a method shown in FIG. 4(a) to FIG. 4(d) or a method shown in FIG. 5(a) to FIG. 5(d). In the method shown in FIG. 4(a) to FIG. 4(d), the electrode films 32 are formed on the quartz-crystal substrate 31, and as previously described, after the hole portion 25 is formed at a predetermined position of the electrode film 32 by wet etching and the metal film patterns in which only the hole portion 25 is opened are obtained, the concave portion 11 is formed at a predetermined position of the quartz-crystal substrate 31 by wet etching as shown in FIG. 4(a) to FIG. 4(d). Concretely, the quartz-crystal substrate 31 on which the electrode film patterns with only the hole portion 25 being opened are formed is immersed in, for example, a hydrofluoric acid solution and is etched with the metal film patterns being used as masks, whereby the concave portion 11 is formed as shown in FIG. 4(b).

Next, as shown in FIG. 4(c), the electrode patterns corresponding to the shapes of the excitation electrodes 21, 22 and the lead electrodes 23, 24 are obtained by the aforesaid wet etching. Thereafter, the resist patterns are removed and the quartz-crystal resonator 1 is cut out from the quartz-crystal substrate 31.

According to this manufacturing method, the electrode films (metal films) are formed on the both surfaces of the quartz-crystal piece 10, the hole portion 25 is subsequently formed in the formation region of the excitation electrodes 21, 22, and the wet etching is thereafter performed with the electrode films in which only the hole portion 25 is opened being used as the masks, whereby the concave portion 11 is formed in the quartz-crystal piece 10. Therefore, a mask for forming the concave portion 11 in the quartz-crystal piece 10 need not be formed separately from the electrode film 32, which can reduce the number of processes and reduce manufacturing cost.

Alternatively, the concave portion 11 may be first formed in the quartz-crystal substrate 31 as in the method shown in FIG. 5(a) to FIG. 5(d). Specifically, the metal films being the masks are formed on the surfaces of the quartz-crystal substrate 31 and a resist pattern corresponding to the shape of the concave portion 11 is formed on the metal film and then the quartz-crystal substrate 31 is immersed in a hydrofluoric acid solution to be etched, whereby the concave portion 11 is formed (refer to FIG. 5(a)). Thereafter, the resist patterns and the metal films are removed.

Next, as shown in FIG. 5(b), after predetermined electrode films (metal films) 35 and resist patterns 36 corresponding to the predetermined electrode patterns are formed on the surfaces of the quartz-crystal substrate 31, the quartz-crystal substrate 31 is immersed in a KI solution to be etched, whereby the electrode patterns are obtained. Thereafter, the resist patterns are removed and the quartz-crystal resonator 1 is cut out from the quartz-crystal substrate 31 (refer to FIG. 5(d)).

### Modification Examples of First Embodiment

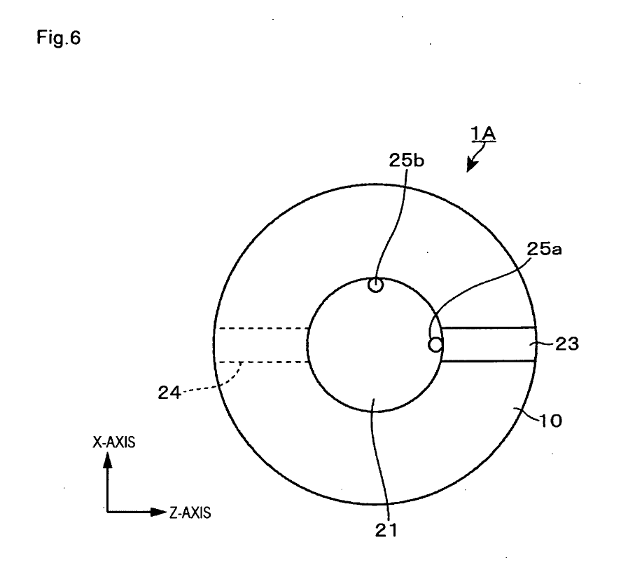

Next, other examples of the quartz-crystal resonator 1 will be described with reference to FIG. 6 to FIG. 8. As shown in FIG. 6, in a quartz-crystal resonator 1A, a plurality of hole portions 25a, 25b and a plurality of concave portions (not shown) which suppress the generation of secondary vibration may be formed according to the secondary vibration being a suppression target. This example has a structure in which the hole portion 25a (and the concave portion) for suppressing overtone vibration generated in a Z-axis direction of a quartz-crystal piece 10 and the hole portion 25b (and the concave portion) for suppressing overtone vibration generated in an X-axis direction of the quartz-crystal piece 10 are provided.

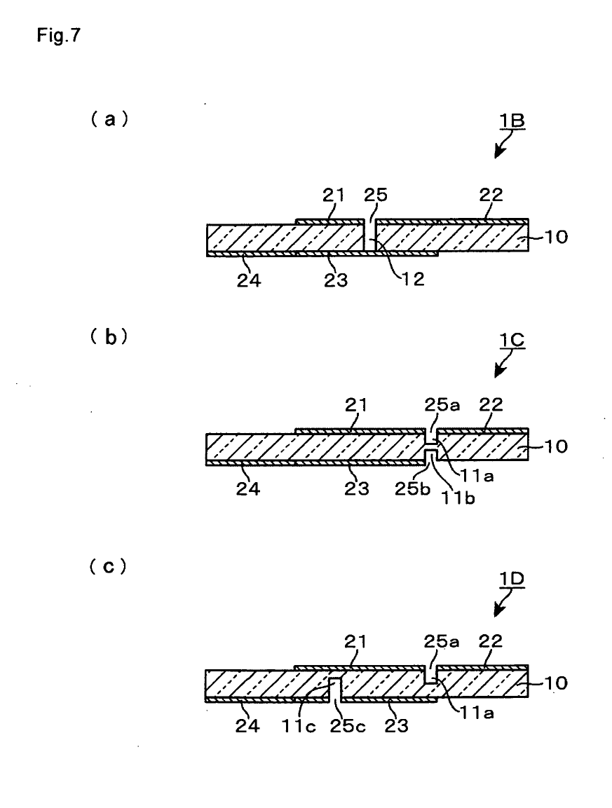

Further, the example shown in FIG. 7(a) has a structure in which a through hole 12 is provided in a quartz-crystal piece 10 so as to continue to a hole portion 25 formed in an excitation electrode 21 on one surface. A structure in this case may be a structure in which the hole portion 25 is formed in the excitation electrode 21 on the one surface and the hole portion 25 is not formed in the excitation electrode 22 on the other surface as shown in FIG. 7(a), or may be a structure, not shown, in which the hole portion is formed not only in the excitation electrode 21 on the one surface but also in the excitation electrode 22 on the other surface so as to continue to the through hole 12. Thus forming the through hole 12 at the position, in the quartz-crystal piece 10, where it can suppress the generation of the secondary vibration can prevent the generation itself of the secondary vibration and is effective. In this example, the hole portion 25 and the through hole 12 correspond to the secondary vibration suppressing part.

Further, as shown in FIG. 7(b) and FIG. 7(c), concave portions 11a, 11b may be formed from both surfaces of a quartz-crystal piece 10 respectively. A quartz-crystal resonator 1C shown in FIG. 7(b) has a structure in which, in order to suppress the generation of one secondary vibration, the concave portions 11a, 11b are formed from a side of a hole portion 25a formed in an excitation electrode 21 on one surface and from a side of a hole portion 25b which is formed in an excitation electrode 22 on the other surface so as to be located at a position facing the hole portion 25a across the quartz-crystal piece 10. Further, a quartz-crystal resonator 1D shown in FIG. 7(c) has a structure corresponding to the suppression of the generation of two secondary vibrations, and has a structure in which a hole portion 25a formed in an excitation electrode 21 on one surface and a concave portion 11a continuing to the hole portion 25a are formed in order to suppress the generation of one of the secondary vibrations, and a hole portion 25c in the excitation electrode 22 on the other surface and a concave portion 11c continuing to the hole portion 25c are formed in order to suppress the generation of the other secondary vibration.

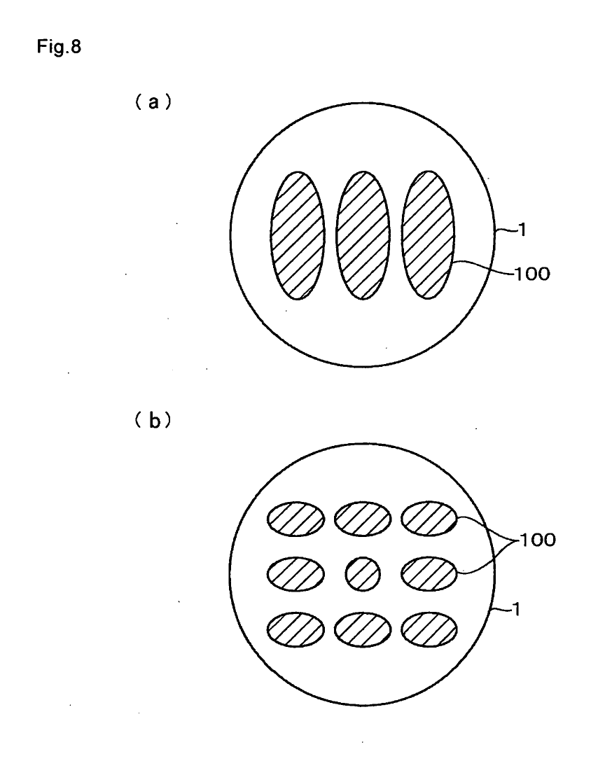

Here, a method of specifying a region of the secondary vibration will be described by using an actual quartz-crystal resonator. A first method can be a method of measuring diffraction intensity of an X ray. The X ray is radiated at a predetermined angle with respect to a normal direction of the quartz-crystal resonator, and the whole surface of the quartz-crystal resonator is scanned by the X ray while an irradiation position of the quartz-crystal resonator is changed, with the angle being fixed, for instance. Then, the diffraction intensity of the X ray at each of the irradiation positions is measured, and a map of the diffraction intensity on the surface of the quartz-crystal resonator is created. Prior to this measurement, a frequency causing the secondary vibration is examined in advance, and the above measurement is performed while an AC voltage with this frequency is applied to the quartz-crystal resonator. FIG. 8(a) and FIG. 8(b) are examples of the map of the X-ray diffraction intensity, in which the hatched regions 100 strongly vibrate.

A second method can be a probe method. In the probe method, while an AC voltage with a pre-examined frequency of secondary vibration is applied between the excitation electrodes of the quartz-crystal resonator, a probe is brought into contact with the surface of the quartz-crystal piece (at a portion where the excitation electrode is present, it penetrates through the excitation electrode), and a voltage is measured by a voltmeter provided between the probe and an earth. Consequently, charge distribution on the surface of the quartz-crystal piece is found, whereby a map similar to that in the first method can be obtained.

The vibration region of the secondary vibration is found in this manner, and the aforesaid concave portion or through hole is formed in this vibration region.

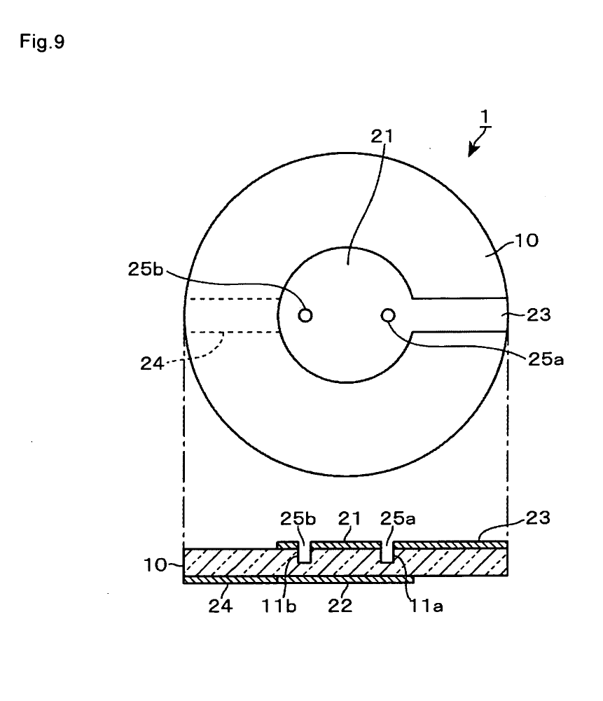

As is seen from FIG. 8(a) and FIG. 8(b), the secondary vibration regions are often symmetrical with respect to the center of the quartz-crystal piece 10, and therefore, the secondary vibration suppressing parts being the concave portions or the through holes formed from the excitation electrode to the quartz-crystal piece 10 are preferably formed symmetrically with respect to the center of the quartz-crystal piece 10. FIG. 9 shows such an example, and a hole portion 25a formed in an excitation electrode 21 and a concave portion 11a formed in a quartz-crystal piece 10 are located symmetrically to a hole portion 25b and a concave portion 11b with respect to a center of the quartz-crystal piece 10.

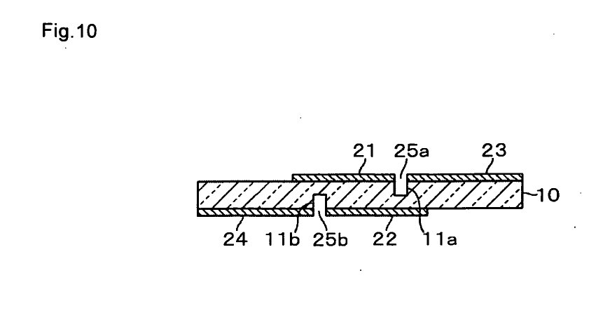

Further, also adoptable is a structure in which, as shown in FIG. 10, a hole portion 25a and a concave portion 11a are formed on one surface of a quartz-crystal piece 10 and the other hole portion 25b and concave portion 11b are formed on the other surface of the quartz-crystal piece 10, and thus the former and the latter are located symmetrically with respect to the center of the quartz-crystal piece 10.

When the secondary vibration suppressing parts are provided so as to be laterally symmetrical to each other, they are laterally well-balanced, and the frequency of the primary vibration is stabilized in the long run compared with a case where they are not laterally well-balanced.

### Second Embodiment

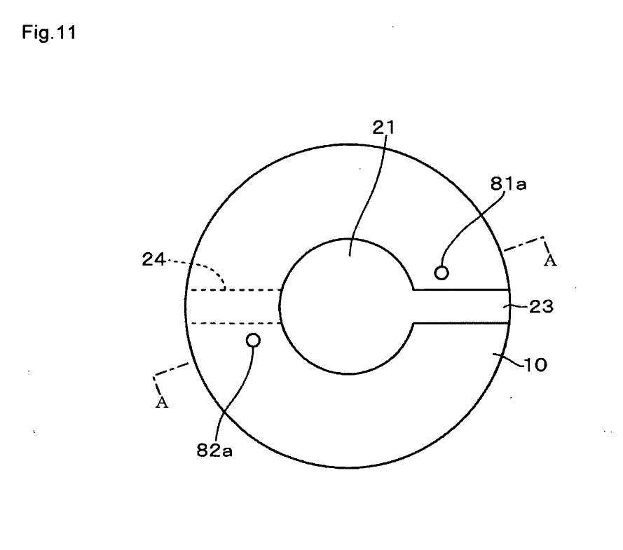

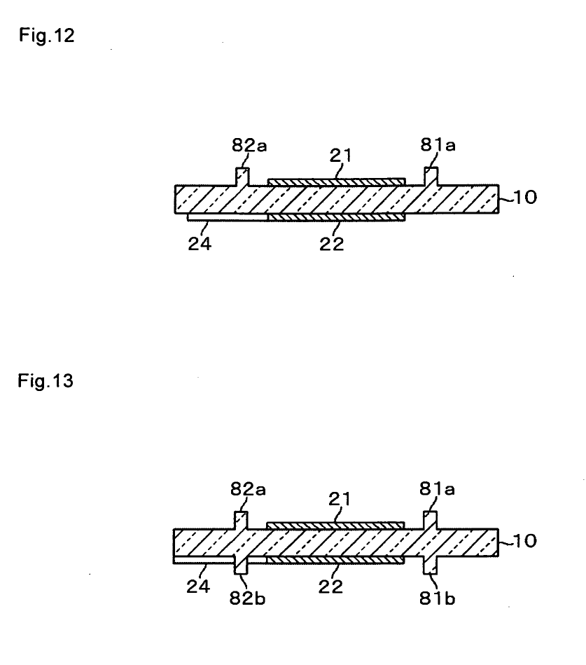

A second embodiment has a structure in which, in a quartz-crystal piece 10, convex portions (projections) are formed in regions where secondary vibration is generated. FIG. 11 and FIG. 12 are views showing such an example, and on one surface of the quartz-crystal piece 10, projections 81a, 82a are formed at two places that are within pre-examined regions where secondary vibration is generated and are apart from excitation electrodes 21, 22. A structure of the projections (convex portions) 81a, 82a can be a columnar projection larger in height than the excitation electrodes 21, 22, for instance, but is not limited to this structure. These projections 81a, 82a are disposed symmetrically to each other with respect to a center of the quartz-crystal piece 10 for the same reason as that described in the final paragraph in the modification examples of the first embodiment.

Further, in an example in FIG. 13, in addition to the structure in FIG. 12, projections 81b, 82b are formed also on the other surface of the quartz-crystal piece 10. These projections 81b, 82b are formed at places corresponding to the projections 81a, 82a on the one surface of the quartz-crystal piece 10, that is, at the same positions as the projections 81a, 82a in plane view.

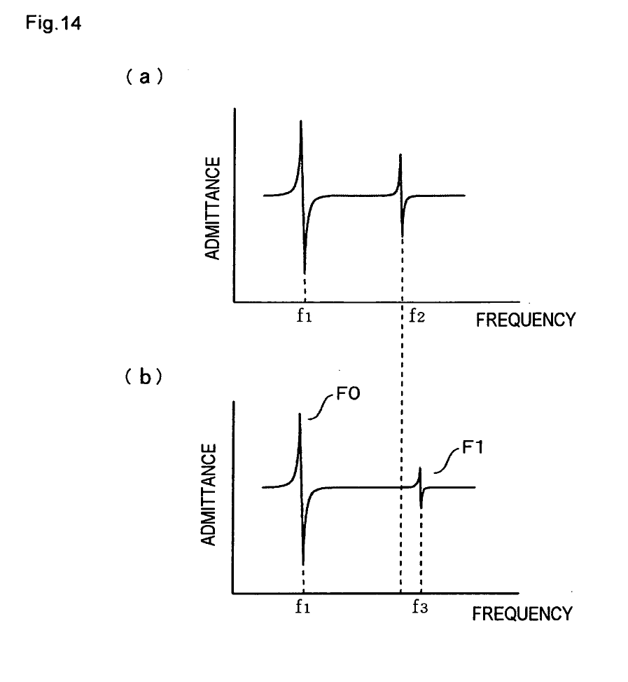

Effects of thus providing the projections on the quartz-crystal piece 10 are shown in FIG. 14(a) and FIG. 14(b). FIG. 14(a) and FIG. 14(b) show a correlation between the oscillation frequency of the quartz-crystal resonator and admittance when the projection is not provided and that when the projection is provided, and f1 represents the frequency of the primary vibration. When the projection is not provided, the secondary vibration is generated with a frequency 12, but when the projection is provided, the frequency f2 shifts in a direction in which it becomes apart from f1 to be f3. Further, the admittance also becomes smaller. It is inferred that, when the projection is thus provided in the region, in the quartz-crystal piece 10, where the secondary vibration is generated, the propagation of the secondary vibration is disturbed and as a result, the secondary vibration is suppressed (the admittance becomes smaller and the frequency shifts).

Further, in the example in FIG. 13, a structure in which the projections 82a and 82b are not provided is also adoptable. In this case, since the projections 81a and 81b are formed at the same positions on the both surfaces of the quartz-crystal piece 10 (the same positions in plane view), they are well-balanced in the thickness direction of the quartz-crystal piece 10. Consequently, deterioration in long-term stability of the frequency of the primary vibration is suppressed. Incidentally, in the second embodiment, the projection may be provided only at one place of the quartz-crystal piece 10.

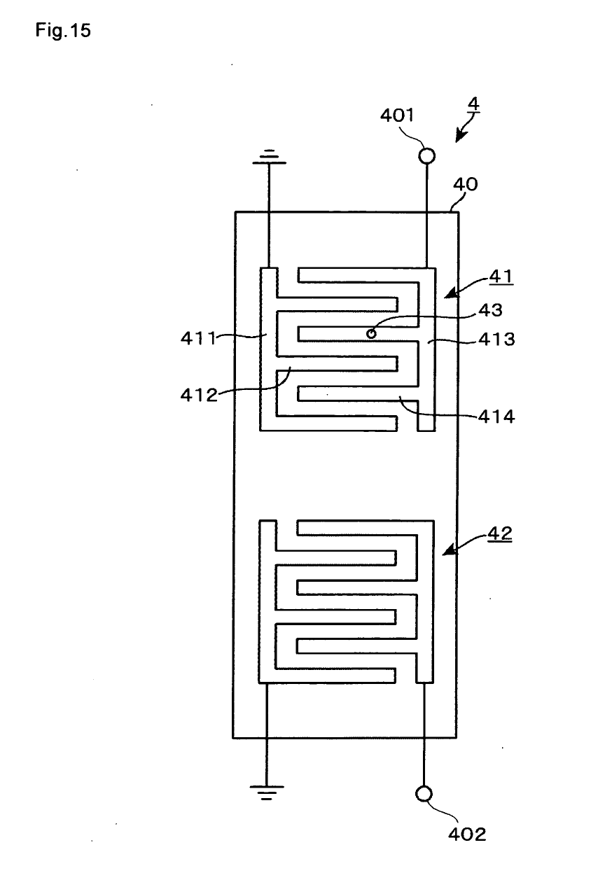

Further, the present invention is also applicable to a SAW (Surface Acoustic Wave) device. 4 in FIG. 15 denotes an elastic wave resonator being an example of the SAW device, and this elastic wave resonator 4 includes a first and a second IDT electrode 41, 42 generating a surface acoustic wave, on longitudinal left and right sides sandwiching a center portion of a piezoelectric body 40 made of an AT-cut quartz-crystal piece, for instance. The first IDT electrode 41 generates, for example, a surface acoustic wave (hereinafter, referred to as SAW) being an elastic wave, by electrical-mechanical conversion of an electric signal input from an input port 401 to the IDT electrode 41. On the other hand, the second IDT electrode 41 plays a role of taking out, as an electric signal, the SAW propagating through an elastic wave waveguide by mechanical-electric conversion of the SAW.

The IDT electrodes 41, 42 have substantially the same structure, and therefore, the structure of, for example, the first IDT electrode 41 will be briefly described. The first IDT electrode 41 is a known IDT (Inter Digital Transducer) electrode made of a metal film of, for example, aluminum, gold, or the like, and has a structure in which a large number of electrode fingers 412, 414 are connected in an alternate finger manner to two bus bars 411, 413 disposed along a propagation direction of the SAW. In each of the IDT electrodes shown in this embodiment, for example, several ten to several hundred electrode fingers are provided, but not all of them are not shown in the drawing.

A hole portion 43 is formed in the first IDT electrode 41 or the second IDT electrode 42 in order to suppress the generation of the secondary vibration. In order to decide a formation position and size of the hole portion 43, the position and size at/with which it suppresses the generation of the secondary vibration is confirmed by a simulator. Further, at a position, in a quartz-crystal piece 40, corresponding to the hole portion 43, a concave portion (not shown) for suppressing the generation of the secondary vibration is formed. A through hole may be formed instead of the concave portion.

In such a SAW device as well, the hole portion 43 is formed at a predetermined position in the IDT electrode and the concave portion is formed at the position, in the quartz-crystal piece 40, corresponding to the hole portion 43. Consequently, the oscillation frequency of the secondary vibration of, for example, thickness shear vibration or the like shifts toward a high frequency side and it is possible to attenuate a gain of the secondary vibration.

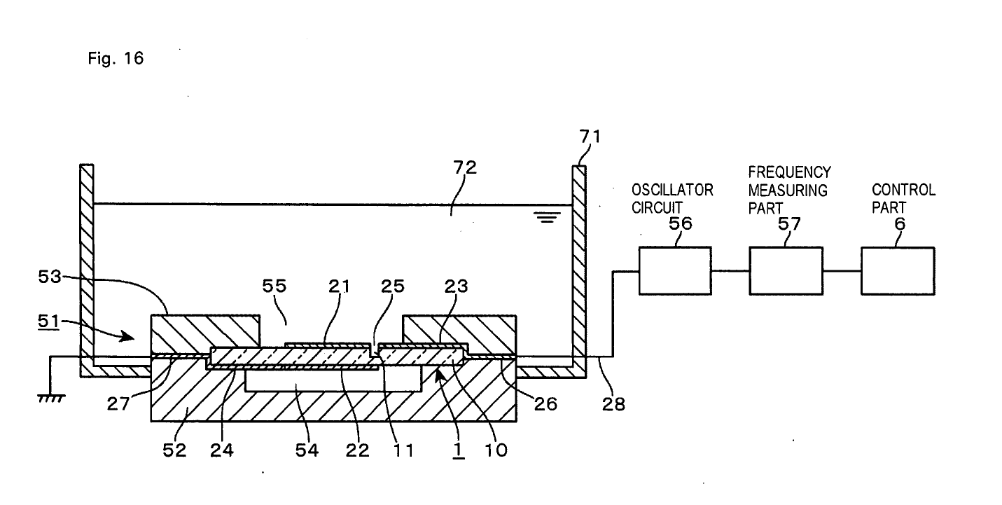

Next, a case where the above-described quartz-crystal resonator 1 is used in an etching amount sensor will be described as an application example of the quartz-crystal resonator 1 with reference to FIG. 16. In the etching amount sensor 5, a quartz-crystal resonator 1 being a piezoelectric resonator is stored in a storage container 51. The quartz-crystal resonator 1 has the same structure as the above-described structure shown in FIG. 1 and secondary vibration being a suppression target is higher in oscillation frequency than primary vibration. The storage container 51 is composed of, for example, a base 52 and a cover 53. A concave portion 54 is formed at a substantially center portion of the base 52, and the quartz-crystal resonator 1 is held in the storage container 51 so that an excitation electrode 22 on the other surface of the quartz-crystal resonator 1 faces an airtight space formed by the concave portion 54.

The cover 53 is provided so as to cover the quartz-crystal resonator 1 placed on the base 52 from an upper side and is airtightly connected to the base 52 in the outside of a region where the quartz-crystal resonator 1 is provided. Further, an opening portion 55 is formed in the cover 53 so that an excitation electrode 21 on one surface of the quartz-crystal resonator 1 and only part of the one surface of a quartz-crystal piece 10 come into contact with an etching solution. That is, the opening portion 55 is formed so as to surround a region on an about 5 mm outer side from the excitation electrode 21, in order to form an etching region around the excitation electrode 21. Further, the cover 53 comes into contact with the etching solution and is therefore made of a material that is etched by the etching solution at a lower etching rate than the quartz-crystal piece 10, for example, polytetrafluoroethylene.

Further, in the storage container 51, wiring electrodes 26, 27 connected to lead electrodes 23, 24 respectively are formed between, for example, the base 52 and the cover 53, and the lead electrodes 23, 24 are electrically connected to the wiring electrodes 26, 27 respectively. For example, the wiring electrode 26 is connected to an oscillator circuit 56 via a signal line 28 and the other wiring electrode 27 is grounded. On a subsequent stage of the oscillator circuit 56, a control part 6 is connected via a frequency measuring part 57. The frequency measuring part 57 plays a role of measuring the oscillation frequency of the quartz-crystal resonator 1 by, for example, digitally processing a frequency signal being an input signal.

The control part 6 has: a function of obtaining data in which a change amount of the oscillation frequency and an etching amount are shown in a correspondence manner in advance and finding a set value of the change amount of the oscillation frequency, which is stored in a memory, corresponding to a target value of an etching amount input by an operator; a function of finding a change amount of the oscillation frequency of the quartz-crystal resonator 1 during the measurement; and a function of outputting a predetermined control signal when the change amount of the oscillation frequency reaches the set value. The control part 6 further has a function of displaying a corresponding etching amount on a display screen, for example, when the change amount of the oscillation frequency obtained during the measurement becomes a predetermined value.

The above etching amount sensor 5 is connected to an etching container 71 so that only one surface of the storage container 51 comes into contact with the etching solution, and consequently, the excitation electrode 21 on the one surface of the quartz-crystal resonator 1 and only part of the one surface of the quartz-crystal piece 10 come into contact with the etching solution 72 in the etching container 71. An object to be processed is not depicted in the etching container 71, but actually the object to be processed being an object to be etched is disposed at a predetermined position in the etching container 71. This predetermined position is a position where a surface to be processed of the object to be processed and the quartz-crystal piece 10 on the one surface of the etching amount sensor 5 come into contact with the etching solution at the same timing.

Next, an operation of the etching amount sensor 5 of the present invention will be described. First, the object to be processed is loaded in the etching container 71, the etching amount sensor 5 is installed in the etching container 71 as previously described, and the predetermined etching solution 72 is supplied into the etching container 71. Further, an operator inputs a target value of the etching amount on the display screen of the control part 6. By thus bringing the object to be processed into contact with the etching solution 72, the etching of the surface to be processed is progressed. Meanwhile, in the etching amount sensor 5, the excitation electrode 21 on the one surface of the quartz-crystal resonator 1 and only part of the one surface of the quartz-crystal piece 10 come into contact with the etching solution 72, and a region, of the one surface of the quartz-crystal piece 10, in contact with the etching solution 72 is etched. As the etching thus progresses and the outside dimension of the quartz-crystal piece 10 becomes smaller, the oscillation frequency of the primary vibration shifts to the high frequency side.

At this time, the etching amount sensor 5 measures the frequency of the frequency signal of the quartz-crystal resonator 1 and stores the measured frequency in the memory. Then, the control signal is output when, for example, the change amount of the oscillation frequency obtained during the measurement reaches the set value, and the object to be processed is carried out from the etching solution by, for example, a not-shown jig, and the etching process is finished.

According to this embodiment, since the hole portion 25 and the concave portion 11 are formed in the quartz-crystal resonator 1, the oscillation frequency of the secondary vibration shifts to the high frequency side and a gain of the secondary vibration reduces. Therefore, even when the etching of the quartz-crystal piece 10 progresses and the oscillation frequency of the primary frequency shifts to the high frequency side, the oscillation frequency of the primary vibration and the oscillation frequency of the secondary vibration do not become equal, which can prevent a frequency jump and accordingly can ensure a large measurement range.

### EXAMPLES

A frequency characteristic of the quartz-crystal resonator 1 with the structure in FIG. 1 was measured. As the quartz-crystal piece 10 of the quartz-crystal resonator 1, an AT-cut quartz-crystal piece oscillated in a fundamental mode was used, the oscillation frequency of the primary vibration was 30 MHz, the diameter of the quartz-crystal piece 10 was φ8.7 mm, the diameter of the excitation electrodes 21, 22 was φ5.0 mm, and the thickness of the quartz-crystal piece 10 was 0.055 mm. The hole portion 25 was circular, with its diameter being φ1.1 mm, and the depth of the concave portion 11 was 0.001 mm. The secondary vibration to be suppressed was vibration with an about 31 MHz oscillation frequency. Further, a frequency characteristic was similarly measured, regarding a quartz-crystal resonator in which the hole portion 25 and the concave portion 11 are not formed in the excitation electrode 21 and the quartz-crystal piece 10 respectively, as a comparative example.

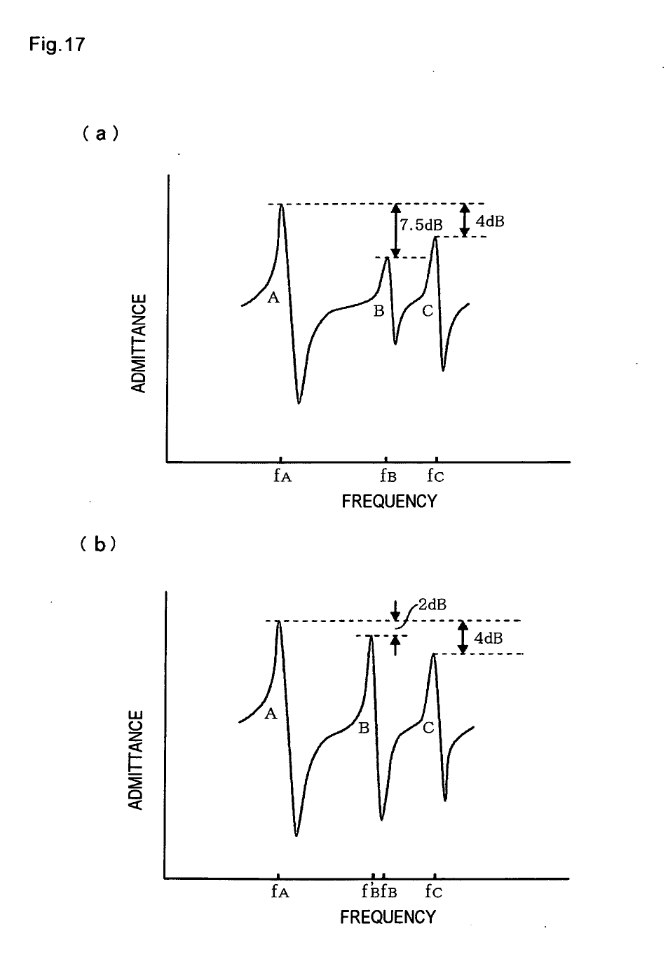

The frequency characteristic obtained at this time in the example is shown in FIG. 17(a) and that in the comparative example is shown in FIG. 17(b). In FIG. 17(a) and FIG. 17(b), the horizontal axis represents frequency and the vertical axis represents admittance. Here, vibration A is primary vibration (primary vibration A), vibration B is overtone vibration generated in the Z-axis direction of the quartz-crystal piece 10 (secondary vibration B), and vibration C is overtone vibration generated in the X-axis direction of the quartz-crystal piece 10 (secondary vibration C). Further, in FIG. 17(a) and FIG. 17(b), fB is an oscillation frequency of the secondary vibration B in the example, and fB′ is an oscillation frequency of the secondary vibration B in the comparative example.

As a result, it has been confirmed that as for the primary vibration A and the secondary vibration C, the oscillation frequency and the gain do not change, but in the example, the secondary vibration B attenuates more compared with the comparative example, and its oscillation frequency fB shifts to a higher frequency side than the oscillation frequency fB′ of the comparative example.

The present invention is applicable not only to a quartz-crystal piece but also to piezoelectric bodies of ceramics and the like, and the primary vibration may be not only the thickness shear vibration but also thickness vertical vibration, thickness twist oscillation, or the like. Further, the secondary vibration to be suppressed of the present invention is not limited to the overtone vibration but includes contour shear vibration and bending vibration. At this time, if the secondary vibration has a higher oscillation frequency than that of the primary vibration, a frequency difference between the oscillation frequency of the primary vibration and the oscillation frequency of the secondary vibration increases when the oscillation frequency of the secondary vibration shifts to the high frequency side, which is especially effective, but forming the through hole in the quartz-crystal piece can produce the effect that even secondary vibration having a lower oscillation frequency than that of the primary vibration can be prevented from being generated. Further, the shape of the quartz-crystal piece is not limited to the circular shape but may be a rectangular shape.

What is claimed is:

1. A piezoelectric resonator comprising:
a piezoelectric body in a plate shape;
excitation electrodes provided on both surfaces of the piezoelectric body; and
a secondary vibration suppressing part including a hole portion formed in the excitation electrode and a concave portion or a through hole formed in a region, in the piezoelectric body, corresponding to the hole, to suppress secondary vibration different in oscillation frequency from primary vibration of the piezoelectric body.

2. A piezoelectric resonator comprising:
a piezoelectric body in a plate shape;
excitation electrodes provided on both surfaces of the piezoelectric body; and
a secondary vibration suppressing part including a convex portion provided on a portion, in the piezoelectric body, apart from the excitation electrode, to suppress secondary vibration different in oscillation frequency from primary vibration of the piezoelectric body.

3. The piezoelectric resonator according to claim 1, wherein a plurality of the secondary vibration suppressing parts are provided symmetrically with respect to a center portion of the excitation electrode.

4. The piezoelectric resonator according to claim 2, wherein the secondary vibration suppressing parts are provided on front and rear surfaces of the piezoelectric body respectively at same positions in plane view.

5. The piezoelectric resonator according to claim 1, wherein the primary vibration is thickness shear vibration, and the secondary vibration is inharmonic overtone vibration.

6. An elastic wave device in which an IDT electrode is provided on a surface of a piezoelectric body in a plate shape, the device comprising:
a secondary vibration suppressing part including a hole portion formed in the IDT electrode and a concave portion or a through hole formed in a region, in the piezoelectric body, corresponding to the hole portion, to suppress an elastic wave with a frequency different from a target frequency band taken out of an output port.

7. An elastic wave device in which an IDT electrode is provided on a surface of a piezoelectric body in a plate shape, the device comprising
a secondary vibration suppressing part including a convex portion provided on a portion, in the piezoelectric body, apart from the IDT electrode, to suppress an elastic wave with a frequency different from a target frequency band taken out from an output port.
